(19) United States
(12) Patent Application Publication
(10) Pub. No.: US 2009/0085143 A1
(43) Pub. Date: Apr. 2, 2009

(54) Image sensor and method of manufacturing the same

(75) Inventor: Byung-Jun Park, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/285,148

(22) Filed: Sep. 30, 2008

(30) Foreign Application Priority Data
Oct. 1, 2007 (KR) 10-2007-0098768

(51) Int. Cl. H01L 27/146; B44C 1/22

(52) U.S. Cl. 257/459; 216/13; 257/E27.141

(57) ABSTRACT

Image sensors and methods of fabricating the same are provided. An image sensor may include a substrate, a first pad provided on a front side of the substrate, a second pad provided on a backside of the substrate, one or more contacts, each of the contacts passing through the substrate and electrically connecting the first pad with the second pad, and one or more guard rings, each of the guard rings surrounding one or more contacts and having insulating characteristics.

### PRIORITY STATEMENT

This application claims priority from Korean Patent Application No. 10-2007-0098768 filed on Oct. 1, 2007 in the Korean Intellectual Property Office, the disclosure of which is hereby incorporated by reference.

### BACKGROUND

1. Field

Example embodiments relate to image sensors and methods of manufacturing the same.

2. Description of the Related Art

Image sensors convert optical images into electrical signals. As the computer industry and the communication industry have developed in recent years, demands for image sensors having improved performance have increased in various fields, e.g., digital cameras, camcorders, PCSs (Personal Communication Systems), games, security cameras, medical micro cameras, and the like. Metal-on-silicon (MOS) image sensors may simply be driven and be embodied in various scanning applications. Further, since a signal processing circuit may be integrated into a single chip, a more compact product is possible. Furthermore, since MOS processing may be compatible with other processes, a decrease in manufacturing cost may be possible. In addition, since the MOS image sensor has low power consumption, a MOS image sensor may be applied to a product that has limited battery capacity. Accordingly, as MOS image sensors have developed, increased resolution has been achieved. For this reason, the demand for MOS image sensors has increased.

A MOS image sensor may include photoelectric transformation elements and a plurality of metal wiring layers. The photoelectric transformation elements absorb incident light and accumulate charges corresponding to the amount of light. The plurality of metal wiring layers receives light and outputs optical signals stored in the photoelectric transformation elements. The incident light may be reflected by the metal wiring layers or absorbed into the interlayer insulating films, which decreases the sensitivity. In addition, reflected light may be absorbed in adjacent pixels, causing crosstalk to occur.

A sensor with the backside of a substrate that is polished, and in which light enters the sensor from the backside of the substrate has been proposed. This structure may be called a BI (backside illuminated) image sensor. Since the BI image sensor does not include a metal wiring layer on the backside where light enters, incident light may not be reflected by a metal wiring layer and/or may not be absorbed into the interlayer insulating films.

### SUMMARY

Example embodiments provide image sensors where a pad is not electrically connected with a substrate and a method of manufacturing image sensors where a pad is not electrically connected with a substrate.

However, the aspects, features and advantages of example embodiments are not restricted to the ones set forth herein. The above and other aspects, features and advantages of example embodiments will become more apparent to one of ordinary skill in the art to which the present invention pertains by referencing the description of example embodiments given below.

According to example embodiments, there is provided an image sensor including, a substrate, a first pad provided on a front side of the substrate, a second pad provided on a backside of the substrate, one or more contacts, each of the contacts passing through the substrate and electrically connecting the first pad with the second pad, and one or more guard rings, each of the guard rings surrounding one or more contacts and having insulating characteristics.

According to example embodiments, there is provided an image sensor further including, the insulated structures that are formed on a front side of the substrate and include a first pad, a buffer film formed on a backside of the substrate, the second pad formed on the buffer film, a contact hole that passes through the buffer film and the substrate, the first pad being exposed externally through the contact hole, a trench that surrounds the contact hole and passes through the buffer film and the substrate, a contact that may be formed in the contact hole and electrically connects the first pad with the second pad, and a guard ring that may be formed in the trench and has insulating characteristics.

According to example embodiments, there is provided a method of manufacturing an image sensor including, a method of manufacturing an image sensor, the method including forming insulated structures, which include a first pad, on a front side of a substrate, forming a buffer film on a backside of the substrate, forming a contact hole passing through the buffer film and the substrate, the first pad being exposed externally through the contact hole, forming a trench that surrounds the contact hole and passes through the buffer film and the substrate, forming a guard ring, which has insulating characteristics, in the trench, forming a contact, which may be electrically connected with the first pad, in the contact hole, and forming a second pad, which may be electrically connected with the contact, on the buffer film.

### BRIEF DESCRIPTION OF THE DRAWINGS

Example embodiments will be more clearly understood from the following detailed description taken in conjunction with the accompanying drawings. FIGS. 1-11 represent non-limiting, example embodiments as described herein.

FIG. 1 is a block diagram of an image sensor according to example embodiments;

FIG. 2 is an example equivalent circuit diagram of the APS array shown in FIG. 1;

FIG. 3 illustrates the image sensor shown in FIG. 1 embodied as an example semiconductor chip;

FIG. 4A shows a layout of a pad that may be used in an image sensor according to example embodiments;

FIG. 4B is an example detailed view of B shown in FIG. 4A;

FIG. 4C is an example cross-sectional view taken along line C-C′ in FIG. 4A;

FIG. 4D is an example view illustrating the effect of a guard ring shown in FIG. 4A;

FIG. 5 is a cross-sectional view showing a pad that may be used in an image sensor according to example embodiments;

FIG. 6 is a cross-sectional view showing a pad that may be used in an image sensor according to example embodiments;

FIG. 7 is a cross-sectional view showing a pad that may be used in an image sensor according example embodiments;

FIG. 8 is a layout illustrating a pad that may be used in an image sensor according to example embodiments;

FIG. 9 is a layout illustrating a pad that may be used in an image sensor according to example embodiments;

FIGS. 10A to 10H are views illustrating methods of manufacturing image sensors according to example embodiments; and

FIG. 11 is a schematic block diagram of a processor-based system including the image sensors according to example embodiments.

### DESCRIPTION OF EXAMPLE EMBODIMENTS

Various example embodiments will now be described more fully with reference to the accompanying drawings in which some example embodiments are shown. In the drawings, the thicknesses of layers and regions may be exaggerated for clarity.

Detailed illustrative example embodiments are disclosed herein. However, specific structural and functional details disclosed herein are merely representative for purposes of describing example embodiments. This invention may, however, be embodied in many alternate forms and should not be construed as limited to only example embodiments set forth herein.

Accordingly, while example embodiments are capable of various modifications and alternative forms, example embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of the invention. Like numbers refer to like elements throughout the description of the figures.

It will be understood that when an element may be referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein may be for the purpose of describing particular example embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the scope of example embodiments. As used herein, the term “and/or” includes any and all combinations of one or more of the associated listed items.

Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the Figures. For example, if the device in the figures is turned over, elements described as “below” or “beneath” other elements or features would then be oriented “above” the other elements or features. Thus, for example, the term “below” may encompass both an orientation which may be above as well as below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that may be consistent with their meaning in the context of the relevant art and will not be interpreted in an idealized or overly formal sense unless expressly so defined herein.

In order to more specifically describe example embodiments, various aspects will be described in detail with reference to the attached drawings. However, the present invention may be not limited to example embodiments described.

Example embodiments described herein will be described referring to plan views and/or cross-sectional views by way of ideal schematic views of the invention. Accordingly, the exemplary views may be modified depending on manufacturing technologies and/or tolerances. Therefore, the example embodiments of the invention are not limited to those shown in the views, but include modifications in configuration formed on the basis of manufacturing processes. Therefore, regions exemplified in figures have schematic properties and shapes of regions shown in figures exemplify specific shapes of regions of elements and not limit aspects of the invention. Preferred example embodiments of the present invention will be described in detail hereinafter with reference to the accompanying drawings so as to describe the present invention in detail.

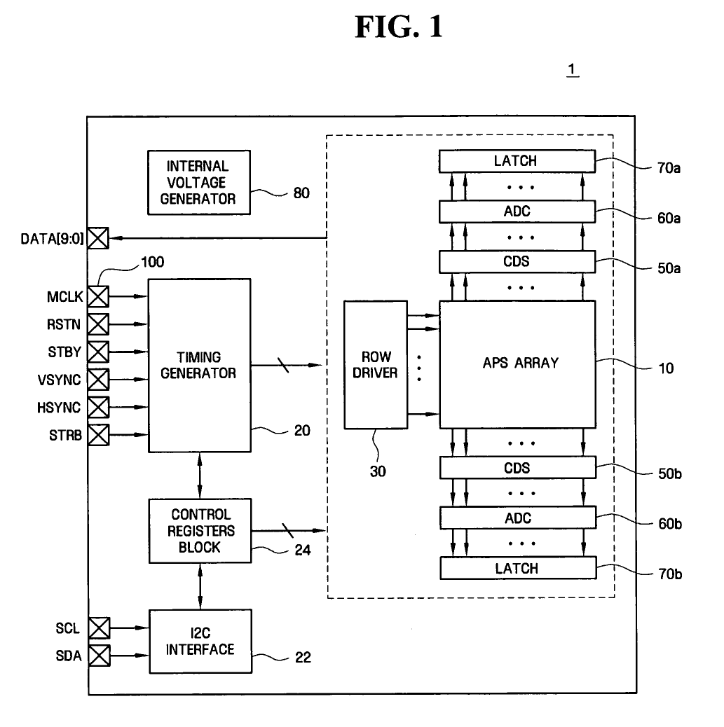

FIG. 1 is a block diagram of an image sensor according to example embodiments. Referring to FIG. 1, an image sensor 1 according to example embodiments may include an active pixel sensor (APS) array 10, a timing generator 20, an I2C interface 22, a control register block 24, a row driver 30, correlated double samplers (CDSs) 50a and 50b, analog-to-digital converters (ADC) 60a and 60b, latches 70a and 70b, an internal voltage generator 80, and pads 100.

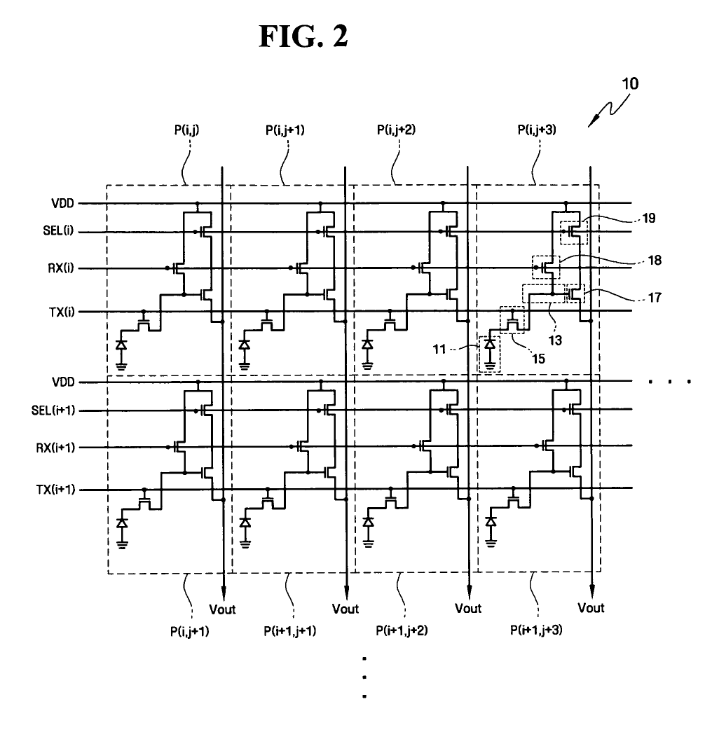

The APS array 10 may include a plurality of pixels arranged in a matrix. The plurality of pixels convert optical images into electrical signals. The APS array 10 may receive a plurality of signals, such as a selection signal SEL, a reset signal RX, and a charge transfer signal TX, from the row driver 30, and may then be driven. The detailed configuration and operation of the APS array 10 will be described below with reference to FIG. 2.

The timing generator 20 may receive a plurality of signals MCLK, RSTN, STBY, VSYNC, HSYNC, and STRB external to the image sensor through pads 100, and send a control signal to the row driver 30 and the like at appropriate timings. MCLK indicates a main clock signal, RSTN indicates a master reset signal, STBY indicates a standby mode signal, VSYNC indicates a vertical synchronization signal, HSYNC indicates a horizontal synchronization signal, and STRB indicates a strobe signal for single frame capture. The signals shown in FIG. 1 are only illustrative, and example embodiments are not limited thereto.

The image sensor shown in FIG. 1 may use a well known I2C interface 22 as a standard serial interface. The I2C interface 22 may receive bi-directional data SDA and a clock SCL. Since the I2C interface 22 is well known, a more detailed description thereof will be omitted.

The electrical signals, which are converted by the pixels of the APS array 10, may be sent to the correlated double samplers 50a and 50b through a vertical signal line. In FIG. 1, the correlated double samplers 50a and 50b are provided on both sides of the APS array 10. However, example embodiments are not limited thereto. For example, electrical signals, which are converted by the pixels positioned on an odd-numbered column, may be sent to the correlated double sampler 50a provided on one side of the APS array. Further, electrical signals, which are converted by the pixels positioned on an even-numbered column, may be sent to the correlated double sampler 50b provided on the other side of the APS array. The correlated double samplers 50a and 50b may perform sampling on and hold the electrical signals sent from the APS array 10. The correlated double samplers 50a and 50b perform double sampling on a noise level and a signal level caused by the generated electric signal, and output levels corresponding to the difference between the noise level and the signal level. The analog-to-digital converters 60a and 60b convert analog signals corresponding to the output levels into digital signals, and output the digital signals. The latches 70a and 70b latch the digital signals, and the latched signals are output through the pads 100.

FIG. 2 is an example equivalent circuit diagram of the APS array shown in FIG. 1. Referring to FIG. 2, pixels P are arranged in a matrix, and form the APS array 10. Each of the pixels P may include a photoelectric transformation element 11, a floating diffusion region 13, a charge transfer element 15, a drive element 17, a reset element 18, and a selection element 19. The operation of the elements will be described using pixels (P(i,j), P(i,j+1), P(i,j+2), P(i,j+3), . . . ), which correspond to an i-th row, as examples.

The photoelectric transformation element 11 may absorb incident light and accumulate charges corresponding to the amount of light. A phototransistor, a photogate, a pinned photodiode, or any combination thereof may be used as the photoelectric transformation element 11. In FIG. 2, a photodiode may be exemplified as the photoelectric transformation element 11. Each of the photoelectric transformation elements 11 may be coupled with each of the charge transfer elements 15, which transfer the accumulated charges to the floating diffusion regions 13. The floating diffusion region (FD) 13 may be a region where charges are converted into voltages. Since the floating diffusion regions 13 may have parasitic capacitance, the charges are accumulated and stored in the floating diffusion regions 13.

The drive element 17, which may be exemplified as a source follower amplifier, may amplify the variation of the electric potential of the floating diffusion region 13 to which the charges accumulated in the photoelectric transformation element 11 are transferred. Then, the electric potential may be output to an output line Vout. The reset element 18 periodically resets the floating diffusion region 13. The reset element 18 may be composed of one MOS transistor driven by a bias, which may be provided through a reset line RX(i) for applying a predetermined and given bias. When the reset element 18 is turned on by the bias provided through the reset line RX(i), predetermined and given electric potential provided to a drain of the reset element 18, may be applied to the floating diffusion region 13, for example, a source voltage VDD.

The selection element 19 selects pixels P that are read in a row. The selection element 19 may be composed of one MOS transistor driven by a bias, which may be provided through a row selection line SEL(i). When the selection element 19 is turned on by the bias provided through the row selection line SEL(i), predetermined electric potential provided to a drain of the selection element 19 may be applied to a drain region of the drive element 17, for example, a source voltage VDD. A transfer line TX(i) for applying a bias to the charge transfer element 15, the reset line RX(i) for applying a bias to the reset element 18, and the row selection line SEL(i) for applying a bias to the selection element 19 may extend in a row direction so as to be substantially parallel to one another.

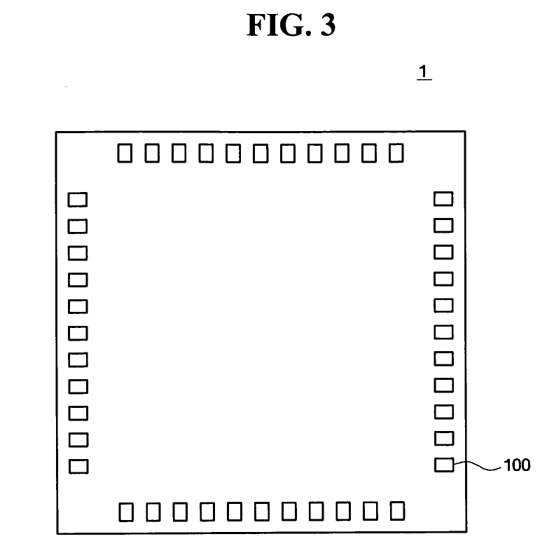

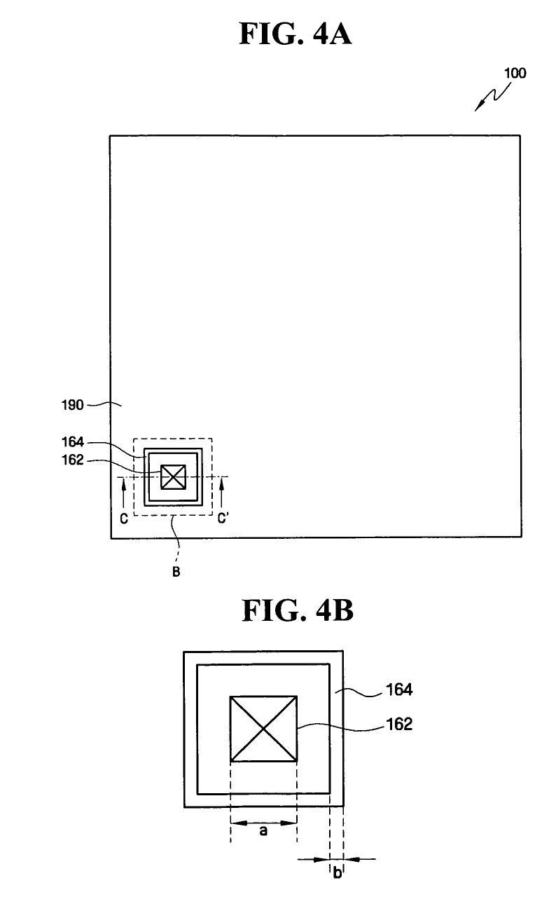

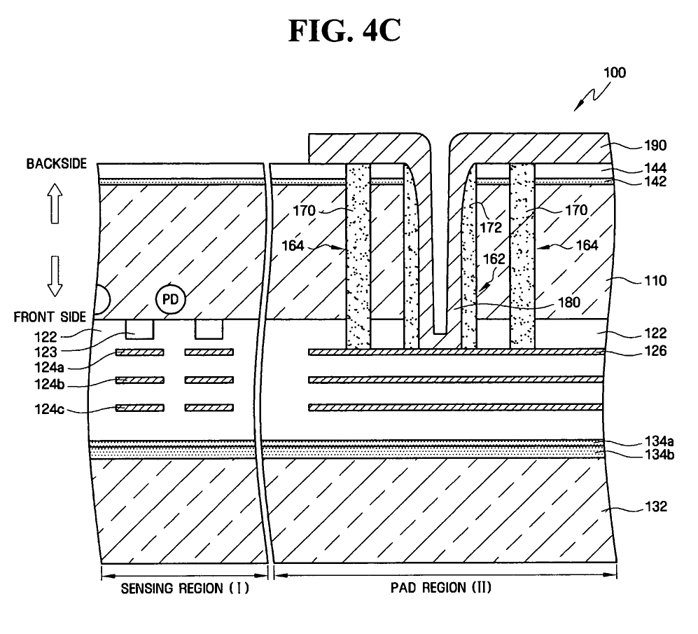

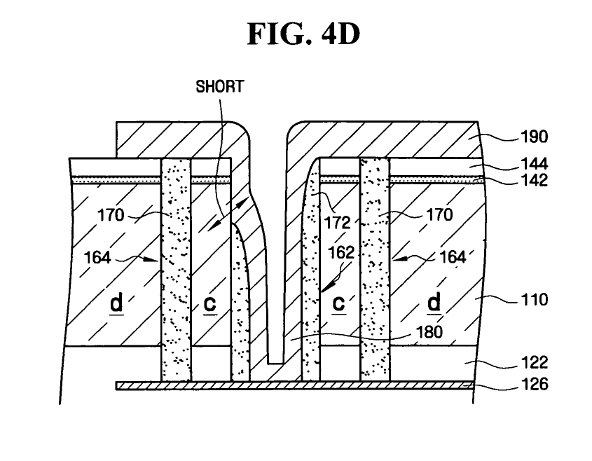

FIG. 3 is an example embodiment showing the image sensor of FIG. 1 may be embodied as an example embodiment single semiconductor chip. FIG. 4A is a layout showing a pad 100 that may be used in an image sensor according to example embodiments. For convenience of description, FIG. 4A shows the pad shown in FIG. 3 in detail. FIG. 4B is a detailed view of B shown in FIG. 4A. FIG. 4C is a cross-sectional view taken along line C-C′ in FIG. 4A. For convenience of description, FIG. 4C shows both a sensing region (I) where an APS array may be formed and a pad region (II) where a pad may be formed. FIG. 4D is a view illustrating a guard ring shown in FIG. 4A.

Referring to FIG. 3, various signals MCLK, RSTN, STBY, VSYNC, HSYNC, STRB, and SCL, data DATA and SDA, voltages, and the like, which have been described with reference to FIG. 1, may be input and/or output through pads 100. As shown in FIG. 3, the pads 100 may be arranged along the edge of the semiconductor chip. The arrangement shown in FIG. 3 is only illustrative, and example embodiments are not limited thereto.

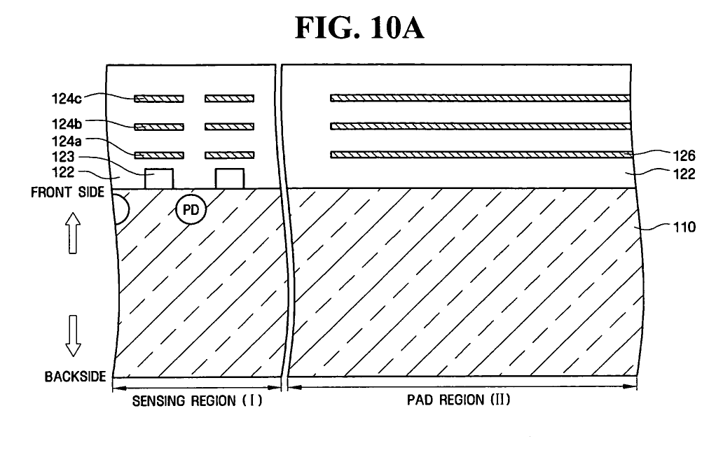

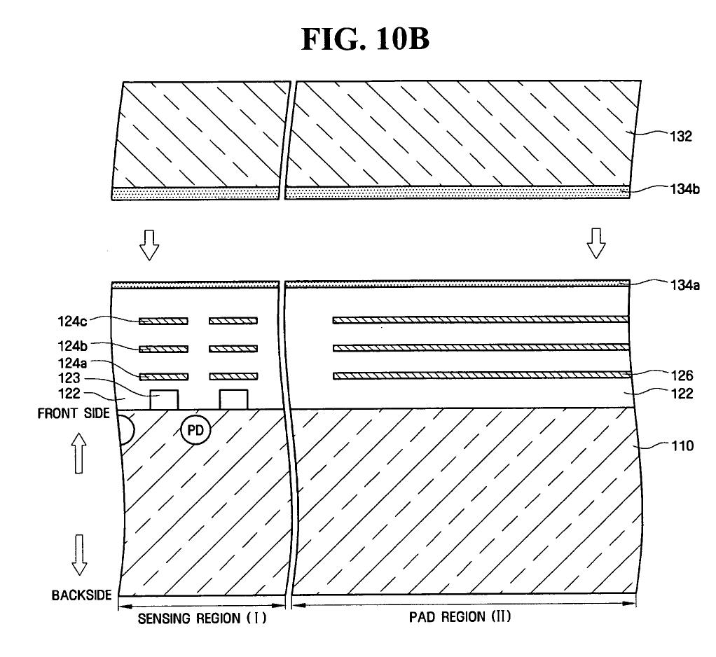

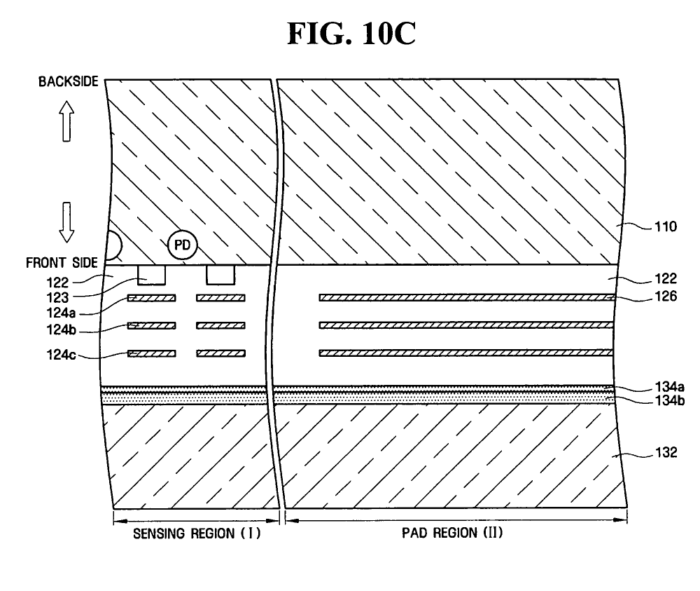

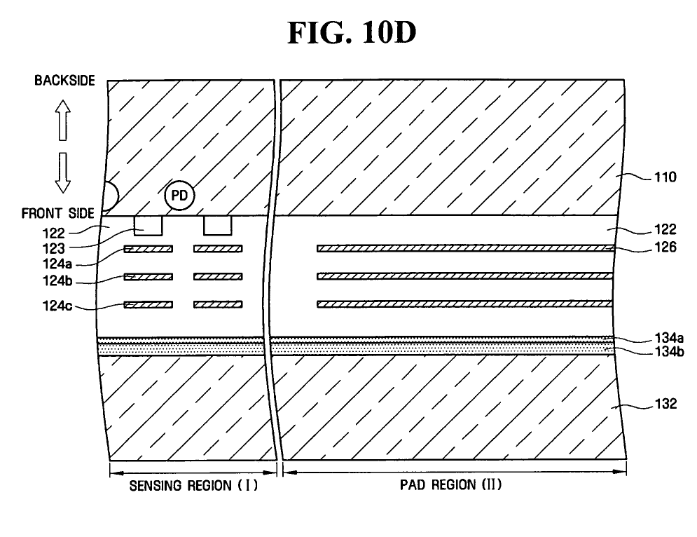

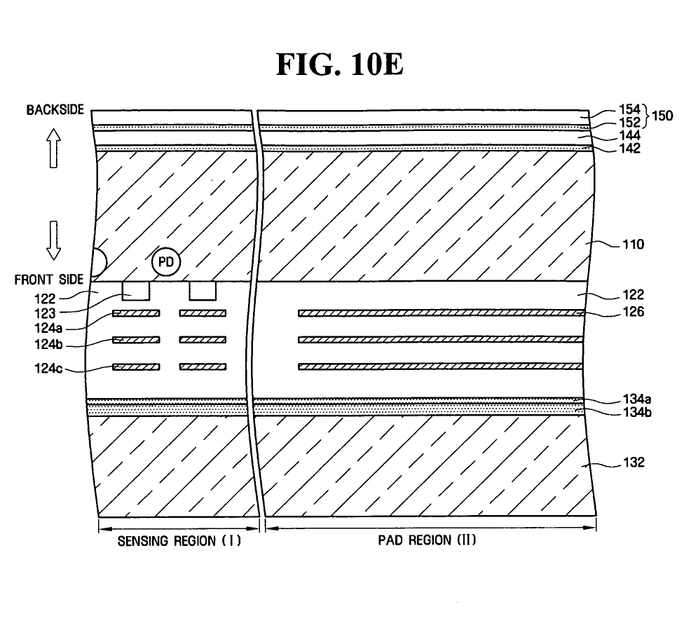

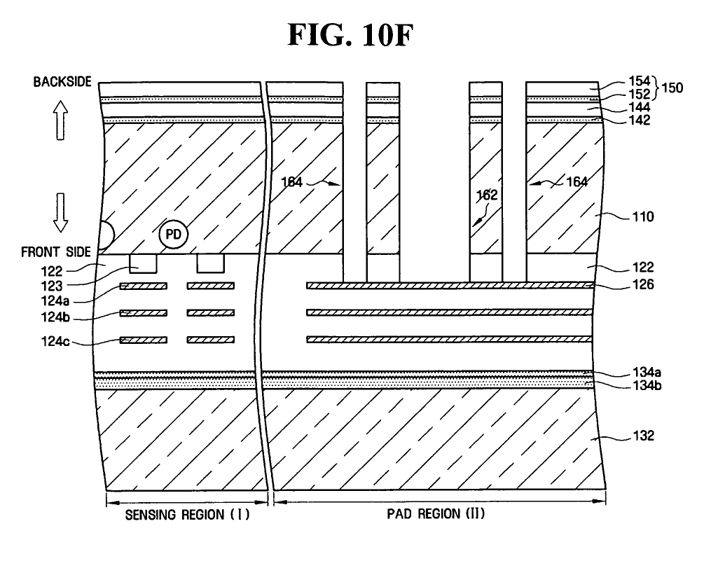

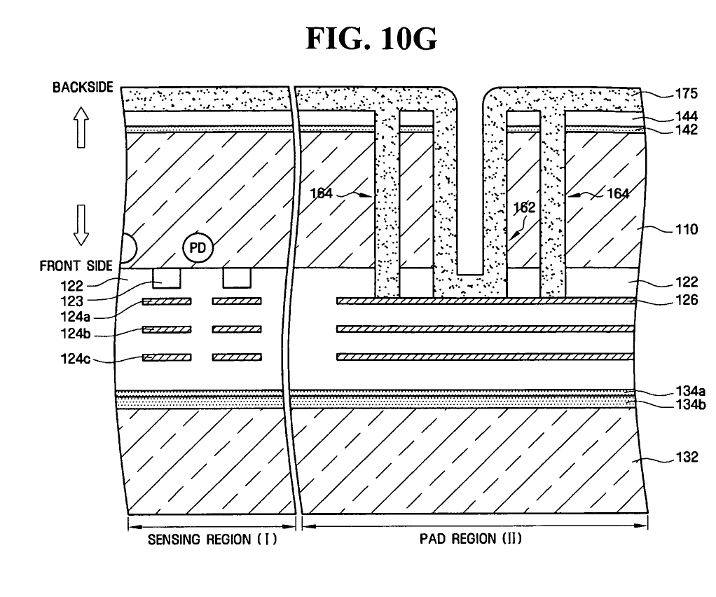

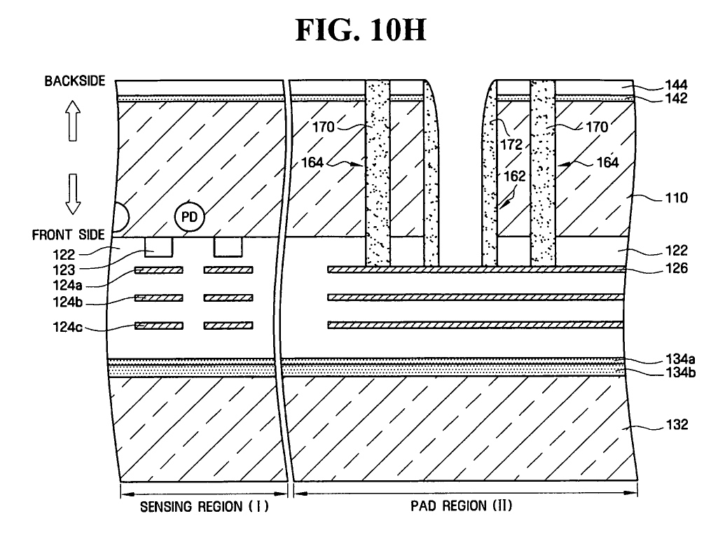

Referring to FIGS. 4A to 4D, a substrate 110 includes the sensing region (1) where the APS array (see reference numeral 10 in FIG. 1) may be formed and the pad region (II) where the pads 100 may be formed. A photoelectric transformation element, for example a photodiode PD may be formed in the sensing region (I) of the substrate 110, and a plurality of gates 123 may be disposed on the substrate 110. The gates 123 may include, for example, a gate of the charge transfer element, a gate of the reset element, and/or a gate of the drive element. Further, various types of substrates 110 may be used, for example, a P-type or N-type bulk substrate, a P-type bulk substrate where a P-type or N-type epitaxial layer may be grown, or a N-type bulk substrate where a P-type or N-type epitaxial layer may be grown. Alternatively, an organic plastic substrate may be used other than a semiconductor substrate. In the substrate 110 shown in FIG. 4C, a bulk substrate may be completely removed by a polishing process (which will be described below with reference to FIG. 10D) leaving only an epitaxial layer. However, example embodiments are not limited thereto. That is, the bulk substrate may partially remain if necessary. The thickness of the remaining substrate 110 may be in the range of, for example, about 3 to 5 μm.

Insulated structures 122, 124a to 124c, and 126 may be disposed on the substrate 110. The insulted structures 122, 124a to 124c and 126 may include an interlayer insulating film 122, a plurality of interconnections 124a to 124c that may be formed on the sensing region (I) and may be sequentially deposited, and a first pad 126 formed in the pad region (II). The first pad 126 may be at the same level in the insulating film 122 as the interconnection 124a, among the plurality of interconnections 124a to 124c. The first pad 126 may be at the same level in the insulating film 122 as the interconnection 124b or 124c, among the plurality of interconnections 124a to 124c, if necessary. The first pad 126 may be made of the same material as the interconnection (124a in FIG. 4C) at the same level.

A supporting substrate 132 may be attached and fixed on the insulated structures 122, 124a to 124c, and 126. The supporting substrate 132 may be used to ensure the strength of the substrate 110 that may be made thin by the polishing process. A semiconductor substrate may be used as the supporting substrate 132. Further, as long as the supporting substrate is made of a material capable of ensuring mechanical strength, any substrate may be used as the supporting substrate. For example, a glass substrate may be used as the supporting substrate.

Adhesive films 134a and 134b may be interposed between the supporting substrate 132 and the insulating structures 122, 124a to 124c, and 126 in order to attach the supporting substrate 132 to the insulating structures 122, 124a to 124c, and 126. If the supporting substrate 132 is a silicon substrate, each of the adhesive films 134a and 134b may be, for example, a silicon oxide film.

Meanwhile, an antireflection film 142 may be disposed on the backside of the substrate 110. The material and thickness of the antireflection film 142 may vary according to the wavelength of light used in a photo process. For example, a silicon oxide film having a thickness of about 50 to 200 Å and a silicon nitride film having a thickness of about 300 to 500 Å may be deposited on one another so as to be used as the antireflection film 142. A buffer film 144 may be disposed on the antireflection film 142. The buffer film 144 reduces or prevents the substrate 110 from being damaged during a patterning process for forming a second pad 190. For example, a silicon oxide film having a thickness of about 3000 to 8000 Å may be used as the buffer film 144.

The image sensor according to example embodiments may include a contact hole 162 and a trench 164 surrounding the contact hole 162. The contact hole 162 may pass through the buffer film 144, the antireflection film 142, and the substrate 110 so that the first pad 126 is exposed externally through the contact hole. A spacer 172 may be formed on the sidewall of the contact hole 162, and a contact 180 may be conformally formed along the spacer 172. In FIG. 4C, the contact 180 has been conformally formed along the spacer 172, but example embodiments are not limited thereto. As long as the contact connects the first pad 126 with the second pad 190, the contact 180 may have any shape. Further, a guard ring 170 having insulating characteristics may be formed in the trench 164. The material of the spacer 172 may be the same as that of the guard ring 170. For example, a silicon oxide film or a silicon nitride film may be used as each of the spacer 172 and the guard ring 170. Furthermore, the material of the spacer 172 may be different from that of the guard ring 170, if necessary.

The spacer 172 reduces or prevents the contact 180 from being electrically connected with the substrate 110 (that is, reduces or prevents a short circuit between the contact and the substrate). If the spacer 172 is abnormally formed or damaged due to process errors, the contact 180 and the substrate 110 may then be electrically connected with each other (see FIG. 4D). The guard ring 170 is formed to completely surround the contact 180 to reduce or prevent the contact from being electrically connected with the substrate. Specifically, as shown in FIG. 4D, even though the contact 180 may be electrically connected with a region c of the substrate 110 due to abnormal formation or damage of the spacer 172, the region c may be electrically isolated by the guard ring 170. Therefore, the contact 180 and region d of the substrate 110 may be electrically connected with each other.

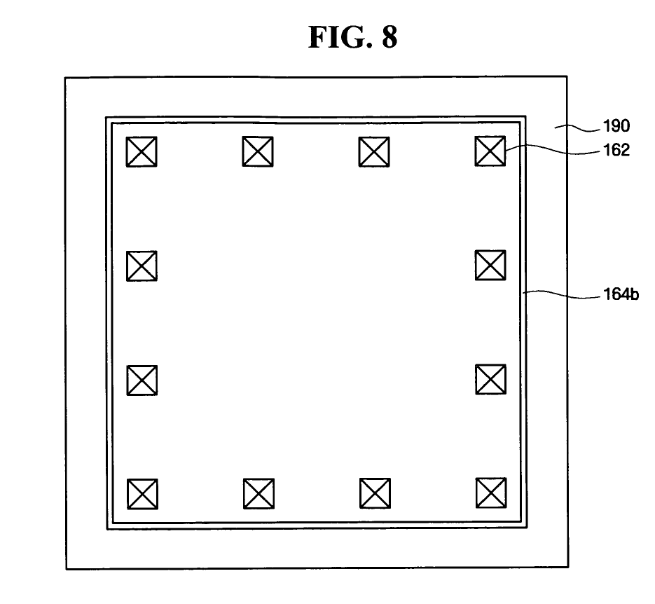

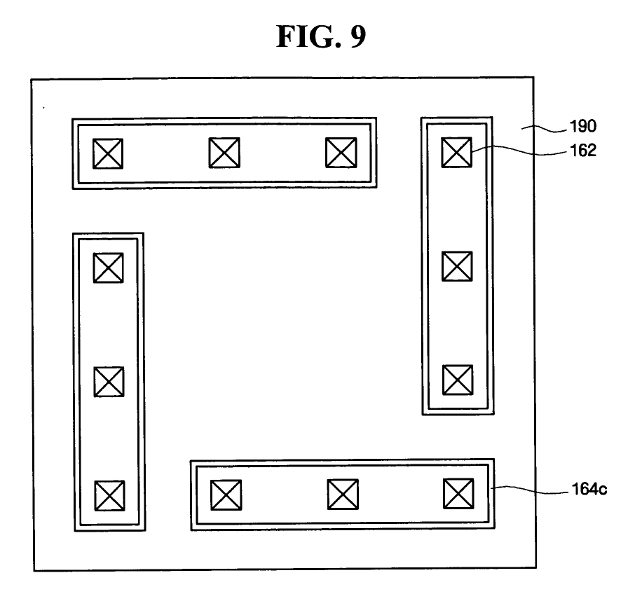

Only one contact hole 162 (or the contact 180) may be formed as shown in FIG. 4A, but example embodiments are not limited thereto. That is, a plurality of contact holes 162 (or contacts 180) may be formed. The higher the number of contact holes 162 or contacts 180, the more the resistance between first pad 126 and second pad 190 may decrease. Accordingly, the number of contacts 180 may be determined in consideration of resistance. FIGS. 8 and 9 exemplify that a plurality of contact holes 162 may be formed.

As shown in FIG. 4B, the width of the contact hole 162 may be larger than the width b of the trench 164. That is, the width of the contact 180 may be larger than that of the guard ring 170. As shown in FIG. 4C, the depth of the contact hole 162 may be equal to that of the trench 164. That is, the length of the contact 180 may be equal to that of the guard ring 170.

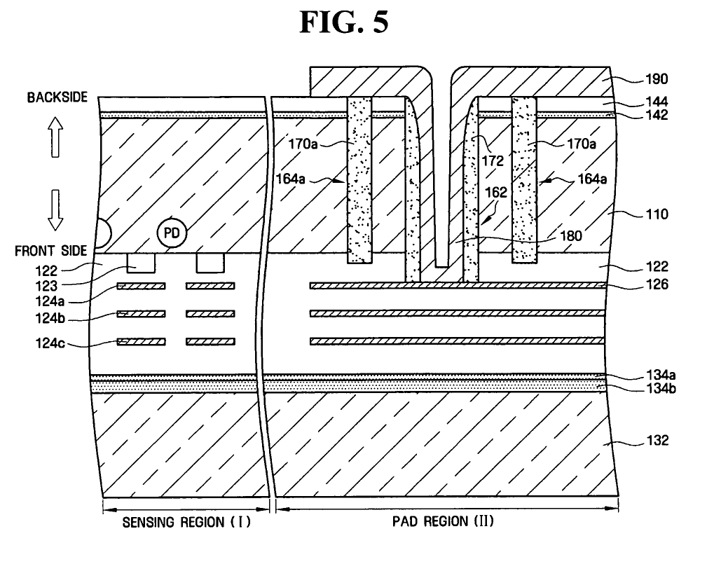

FIG. 5 is a cross-sectional view showing a pad that may be used in an image sensor according to example embodiments. Referring to FIG. 5, the depth of trench 164a may be smaller than that of contact hole 162. That is, the length of guard ring 170a may be smaller than that of contact 180. As described with reference to FIGS. 4A to 4D, the guard ring 170a reduces or prevents the contact 180 from being electrically connected with the substrate 110. Accordingly, the trench 164a does not need to extend to a first pad 126. For example, the trench 164a may have a depth such that the contact 180 may not be electrically connected with a substrate 110 and/or may extend to an interlayer insulating film 122.

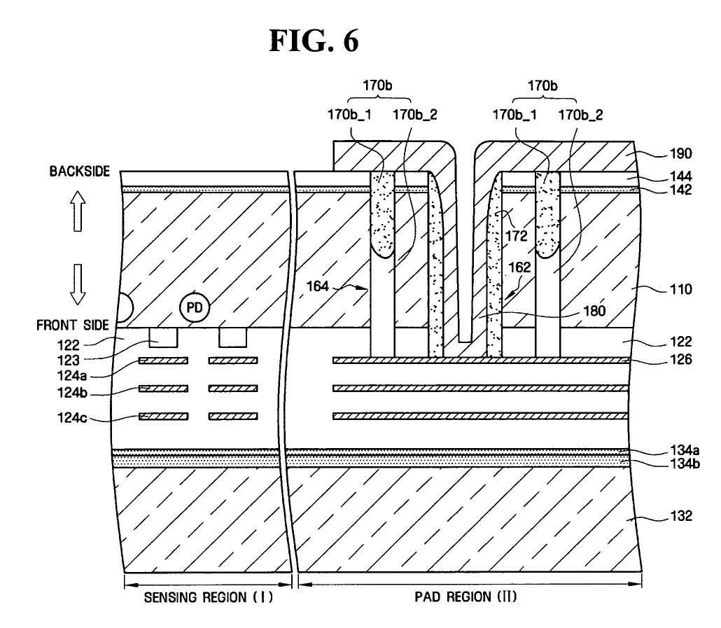

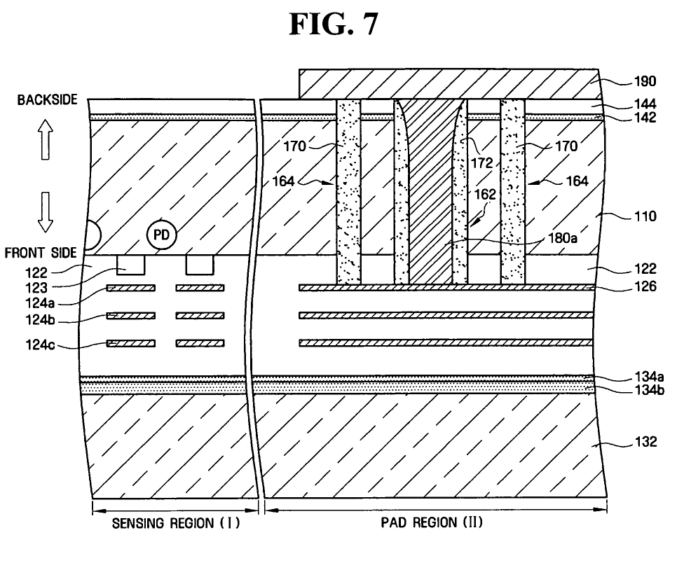

FIG. 6 is a cross-sectional view showing a pad that may be used in an image sensor according to example embodiments. Referring to FIG. 6, a part of a trench 164 may be filled with an insulating material 170b_1, and the other portion of the trench may be filled with air 170b_2. Since the width of the trench 164 may be very small, the trench 164 may not be completely filled with the insulating material 170b_1. However, since the air 170b_2 also has insulating characteristics, a guard ring 170b may be used to electrically isolate contact 180 from substrate 110. FIG. 7 is a cross-sectional view showing a pad that may be used in an image sensor according to example embodiments. Referring to FIG. 7, contact hole 162 may be completely filled with contact 180a. FIG. 8 is a layout illustrating a pad that may be used in an image sensor according to example embodiments. Referring to FIG. 8, a plurality of contact holes 162 may be formed and a trench 164b may be formed to surround all of the contact holes 162. For example, a guard ring 170 formed in the trench 164b may be formed to surround all of contacts 180 that electrically connect a first pad 126 with a second pad 190.

FIG. 9 is a layout illustrating a pad that may be used in an image sensor according to example embodiments. Referring to FIG. 9, trenches 164c are formed to surround two or more contact holes 162. For example, a guard ring 170 formed in each of the trenches 164c may be formed to surround two or more contacts 180 and/or the guard ring 170 may be formed to surround three contacts or four contacts. It will be apparent to those skilled in the art that the number of the contacts 180 surrounded by the guard ring 170 may vary depending on layout design. Although not shown in the drawings, a plurality of contacts 180 (or contact holes 162) may be formed and a plurality of guard rings 170 (or trenches 164) may surround one corresponding contact 180 (or contact hole 162), respectively.

Methods of manufacturing image sensors according to example embodiments will be described hereinafter with reference to FIGS. 10A to 10H and 4C. Referring to FIG. 10A, element isolation regions (not shown), such as STI (Shallow Trench Isolation) or DTI (Deep Trench Isolation), are formed on a substrate 110 to define a sensing region (I) and a pad region (II) on the substrate 110. Subsequently, a plurality of pixels may be formed in the sensing region (I). Specifically, a photoelectric transformation element, for example, a photodiode PD may be formed in the sensing region (I), and a plurality of gates 123 may be formed on the sensing region (I). The gates 123 may include, for example, a gate of the charge transfer element, a gate of the reset element, and/or a gate of the drive element.

Insulated structures 122, 124a to 124c, and 126 may then be formed on the front side of the substrate 110. Specifically, the insulated structures 122, 124a to 124c and 126 may include an interlayer insulating film 122, a plurality of interconnections 124a to 124c that may be formed on the sensing region (I) and sequentially deposited, and a first pad 126 formed in the pad region (II). The first pad 126 may be at the same level as the interconnection 124a, among the plurality of the interconnections 124a to 124c.

Referring to FIG. 10B, a supporting substrate 132 may be attached to the insulated structures 122, 124a to 124c, and 126. Specifically, an adhesive film 134a may be formed on the insulated structures 122, 124a to 124c, and 126, and the surface of the adhesive film 134a may be planarized. An adhesive film 134b may be formed on the supporting substrate 132. After that, the adhesive films 134a and 134b are allowed to face each other thereby attaching the substrate 110 and the supporting substrate 132 to each other.

Referring to FIG. 10C, the substrate 110 may be turned over. Referring to FIG. 10D, the backside of the substrate 110 may be polished. Specifically, the backside of the substrate 110 may be polished using CMP (Chemical Mechanical Polishing), BGR (Back Grinding), reactive ion etching, or any combination thereof. The thickness of the polished substrate 110 may be in the range of, for example, about 3 to 5 μm.

Referring to FIG. 10E, an antireflection film 142 may be formed on the backside of the substrate 110. For example, the antireflection film may be formed using a CVD (Chemical Vapor Deposition) method by depositing a silicon oxide film having a thickness of about 50 to 200 Å and a silicon nitride film having a thickness of about 300 to 500 Å. Subsequently, a buffer film 144 may be formed on the antireflection film 142. For example, the buffer film may be formed using a CVD method by depositing a silicon oxide film having a thickness of about 3000 to 8000 Å. Then, a hard mask film 150 may be formed on the buffer film 144. For example, the hard mask film may be formed using a CVD method by depositing a silicon nitride film 152 having a thickness of about 1000 to 2000 Å and a silicon oxide film 154 having a thickness of about 3000 to 10000 Å.

Referring to FIG. 10F, a contact hole 162 and a trench 164 may be formed. Specifically, a photoresist pattern (not shown) may be formed on the hard mask film 150, and the hard mask film 150 may be patterned using the photoresist pattern. Then, the photoresist pattern may be removed. A contact hole 162 and a trench 164 may be formed using the patterned hard mask film 150. The contact hole 162 passes through the buffer film 144, the antireflection film 142, and the substrate 110, and the first pad 126 may be exposed externally through contact hole 162. The trench 164 passes through the buffer film 144, the antireflection film 142, and the substrate 110, and surrounds the contact hole 162. The contact hole 162 and the trench 164 may be formed, e.g., by anisotropic etching.

In FIG. 10F, the contact hole 162 and the trench 164 may be simultaneously formed using one hard mask film 150. However, example embodiments are not limited thereto. If necessary, the contact hole 162 and the trench 164 may be formed by separate processes, respectively.

Referring to FIG. 10G, the hard mask film 150 may be removed. The contact hole 162 and the trench 164 may be filled with an insulating material 175 by using a CVD method. In example embodiments, since the width of the trench 164 may be smaller than that of the contact hole 162, the trench 164 may be completely filled with the insulating material 175. However, the contact hole 162 may be not completely filled with the insulating material 175.

Referring to FIG. 10H, an etch back process is performed on the insulating material (175 in FIG. 10G) so that the first pad 126 is exposed externally. Due to the etch back process, a spacer 172 may be formed on the sidewall of the contact hole 162, and a guard ring 170 may be formed in the trench 164. Referring to FIG. 4C, the contact 180 and the second pad 190 are formed. Specifically, a conductive material (not shown) may be conformally formed along the buffer film 144 and the spacer 172, and the conductive material may be patterned. Accordingly, the contact 180 and the second pad 190 are simultaneously formed. The contact 180 and the second pad 190 have been simultaneously formed herein, but example embodiments are not limited thereto. If necessary, the contact may be formed by a separate process, and the second pad 190 may also then be formed by a separate process. Similar methods may be used to manufacture the image sensors according to example embodiments and therefore further description thereof will be omitted.

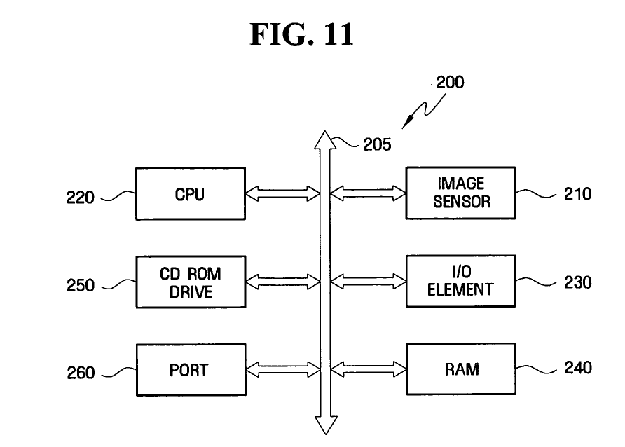

FIG. 11 is a schematic block diagram of a processor-based system including the image sensors according to example embodiments. Referring to FIG. 11, a processor-based system 200 is a system for processing an output image of a CMOS image sensor 210. The processor-based system 200 may include a computer system, a camera system, a scanner, a mechanized clock system, a navigation system, a videophone, a supervisory system, an autofocus system, a tracking system, a motion monitoring system, and/or an image stabilization system. However, the processor-based system is not limited thereto.

The processor-based system 200 such as a computer system may include a CPU 220 such as a microprocessor that may communicate with an I/O element 230 through a bus 205. The CMOS image sensor 210 may be communicate with the system through the bus 205 or another communication link. Further, the processor-based system 200 may further include a RAM 240, a CD ROM drive 250, and/or a port 260, which may communicate with the CPU 220 through the bus 205. The port 260 may include a port, which may be used to couple a video card, a sound card, a memory card, and/or a USB device, and a port that may be used to communicate with another system so as to transmit data. The CMOS image sensor 210 may be integrated together with the CPU, a digital signal processor (DSP), and/or a microprocessor. Further, the CMOS image sensor may be integrated together with a memory. The CMOS image sensor may be integrated into a chip unrelated to a processor, if necessary.

Although example embodiments have been described in connection with FIGS. 1-11, it will be apparent to those skilled in the art that various modifications and changes may be made thereto without departing from the scope and spirit of example embodiments. Therefore, it should be understood that the above example embodiments are not limited, but illustrative in all aspects.

According to the above-described image sensors and methods of manufacturing image sensors, it may be possible to reduce or prevent the pads from being electrically connected with the substrate.

The foregoing may be illustrative of example embodiments and may not be construed as limiting thereof. Although example embodiments have been described, those skilled in the art will readily appreciate that many modifications are possible in example embodiments without materially departing from the novel teachings and advantages. Accordingly, all such modifications are intended to be included within the scope of this invention as defined in the claims. In the claims, means-plus-function clauses are intended to cover the structures described herein as performing the recited function, and not only structural equivalents but also equivalent structures. Therefore, it may be understood that the foregoing may be illustrative of various example embodiments and may not be construed as limited to the specific example embodiments disclosed, and that modifications to the disclosed example embodiments, as well as other example embodiments, are intended to be included within the scope of the appended claims.

What is claimed is:

1. An image sensor comprising:
a substrate;
a first pad on a front side of the substrate;
a second pad on a backside of the substrate;
one or more contacts, each of the contacts passing through the substrate and electrically connecting the first pad with the second pad; and
one or more guard rings, each of the guard rings surrounding one or more contacts and having insulating characteristics.

2. The image sensor of claim 1, wherein a width of the guard ring is smaller than a width of the contact.

3. The image sensor of claim 1, wherein a length of the guard ring is equal to or smaller than a length of the contact.

4. The image sensor of claim 1,
wherein the number of the contacts is two or more,
the number of guard rings is two or more, and
each of the guide rings surrounds one corresponding contact.

5. The image sensor of claim 1,
wherein the number of the contacts is two or more,
the number of the guard rings is one, and
the guard ring surround all of the contacts.

6. The image sensor of claim 1, further including:
insulated structures on the front side of the substrate, which include the first pad;
a buffer film on the backside of the substrate on which the second pad is formed;
one or more contacts that pass through the buffer film and the substrate, and electrically connect the first pad to the second pad; and
one or more guard rings formed therein, wherein the one or more guard rings have insulating characteristics, and the one or more guard rings surround the one or more contacts and pass through the buffer film and the substrate.

7. The image sensor of claim 6, wherein a width of the one or more guard rings are smaller than a width of the one or more contacts.

8. The image sensor of claim 6, wherein a depth of the one or more guard rings is equal to or smaller than a depth of the contact hole.

9. The image sensor of claim 6, wherein the one or more contacts are conformally formed along one or more spacers.

10. The image sensor of claim 6, wherein the spacers and the one or more guard rings are made of the same material.

11. The image sensor of claim 6, wherein the substrate includes a sensing region and a pad region,
the insulated structures include a plurality of interconnections that are sequentially deposited on the sensing region, and
the first pad is positioned at the same level as an interconnection among the plurality of interconnections.

12. A method of manufacturing an image sensor, the method comprising:
forming insulating structures, which include a first pad, on a front side of a substrate;
forming a buffer film on a backside of the substrate;
forming one or more contact holes passing through the buffer film and the substrate, the first pad being exposed externally through the one or more contact holes;
forming one or more trenches that surround the one or more contact holes and pass through the buffer film and the substrate;
forming one or more guard rings in the one or more trenches, which have insulating characteristics;
forming one or more contacts in the one or more contact holes, which are electrically connected with the first pad; and
forming a second pad, which is electrically connected with the one or more contacts on the buffer film.

13. The method of claim 12, wherein a width of the one or more trenches is smaller than a width of the one or more contact holes.

14. The method of claim 12, wherein a depth of the one or more trenches is equal to or smaller than a depth of the one or more contact holes.

15. The method of claim 12, wherein the forming of the one or more contact holes and the forming of the one or more trenches are performed at the same time.

16. The method of claim 12, further comprising:
forming a spacer on a sidewall of the one or more trenches.

17. The method of claim 16, wherein the forming of the spacer and the forming of the one or more guard rings are performed at the same time, and
the forming of the spacer and the forming of the one or more guard rings include filling the one or more contact holes and the one or more trenches with an insulating material, and performing an etch back of the insulating material so that the first pad is exposed externally.

18. The method of claim 16, wherein the forming of the one or more contacts and the forming of the second pad are performed at the same time, and
the forming of the one or more contacts and the forming of the second pad include conformally forming a conductive material along the buffer film and the spacer, and patterning the conductive material.

19. The method of claim 12, wherein
the substrate includes a sensing region and a pad region,
the insulated structures further include a plurality of interconnections that are sequentially deposited on the sensing region, and
the first pad is at the same level as an interconnection among the plurality of the interconnections.

20. A system for processing an image comprising:
a bus;
at least one processor communicatively coupled to the bus;
an input/output element communicatively coupled to the bus; and
the image sensor of claim 1 communicatively coupled to the bus.

21. The system of claim 20, further including at least one RAM, CD ROM drive, and communication port, communicatively coupled to the bus.

22. The system of claim 20, wherein the image sensor is integrated with the at least one processor.
